(19) United States
(12) Patent Application Publication
(10) Pub. No.: US 2011/0237024 A1
(43) Pub. Date: Sep. 29, 2011

(54) METHOD FOR PROCESSINIG AN EDGE OF A PHOTOVOLTAIC PANEL

(75) Inventors: Chang-Han CHIANG, Hsinchu County (TW); Chih-Ming Lin, Hsinchu County (TW); Cheng-Hsin Chen, Changhua County (TW)

(73) Assignee: Du Pont Apollo Limited, Hong Kong (HK)

(21) Appl. No.: 13/052,119

(22) Filed: Mar. 21, 2011

Related U.S. Application Data
(60) Provisional application No. 61/317,687, filed on Mar. 25, 2010.

(51) Int. Cl. H01L 31/0224

(52) U.S. Cl. 438/98; 257/E31.126

(57) ABSTRACT

A method for processing an edge of a photovoltaic panel is described. A first electrically-conductive film, a photovoltaic film and a second electrically-conductive film are serially formed as a stack of three films over a surface of a substrate. An edge section of the stack of three films is removed from the surface of the substrate by sandblasting. At least two separate grooves are formed by laser scribing on all the three films adjacent to the removed edge section of the stack of three films.

### RELATED APPLICATIONS

This application claims priority to U.S. Provisional Application Ser. No. 61/317,687, filed Mar. 25, 2010, which is herein incorporated by reference.

### BACKGROUND

1. Field of Invention

The present invention relates to a photovoltaic device and method for manufacturing the same.

2. Description of Related Art

In recent years, awareness of ecological problems has been raised worldwide. Among other things, the global warming resulting from CO₂ emission is a serious concern, and clean energy has been increasingly desired. In such a circumstance, a solar cell shows great promise to serve as a source of clean energy in terms of its safety and operability.

When using solar cell modules, durability with respect to the external environment, including temperature, humidity, and impact, is required. Therefore, ordinary solar cell modules are constructed such that: solar cells are sealed with a filler; a weather-resistant film or glass is provided as a protective material on the top surface side thereof; and a reinforcing member or outer member is mounted on the periphery and bottom surface thereof. Most of such members are made of a metal.

Besides, an additional electrical isolation is essential for an all edges of a solar cell module. There are several conventional ways, e.g. sandblasting, for processing the edges of a solar cell module, but some are not cost-friendly and thus add cost to the final product.

For the forgoing reasons, there is a need for improving the solar panel's edge processing method.

### SUMMARY

It is therefore an objective of the present invention to provide a cost-effective processing method for establishing an electrical isolation on an edge of a photovoltaic panel.

In accordance with the foregoing and other objectives of the present invention, a method for processing an edge of a photovoltaic panel is provided. A first electrically-conductive film, a photovoltaic film and a second electrically-conductive film are serially formed as a stack of three films over a surface of a substrate. An edge section of the stack of three films is removed from the surface of the substrate by sandblasting. At least two separate grooves are formed by laser scribing on all the three films adjacent to the removed edge section of the stack of three films.

According to a preferred embodiment disclosed herein, the removed edge section of the stack of three films ranges from about 9 mm to about 12 mm in width.

According to another preferred embodiment disclosed herein, the edge section of the electrically-conductive film is less than 12 mm in width.

According to another preferred embodiment disclosed herein, the removed edge section of the stack of three films is less than 12 mm in width.

According to another preferred embodiment disclosed herein, the least two separate grooves are in parallel with the removed edge section of the stack of three films.

According to another preferred embodiment disclosed herein, the first electrically-conductive film is a transparent conducting oxide film.

According to another preferred embodiment disclosed herein, the second electrically-conductive film is a transparent conducting oxide film.

According to another preferred embodiment disclosed herein, each of the at least two separate grooves is about 250 μm in width.

According to another preferred embodiment disclosed herein, the substrate is a glass substrate.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a top view of a photovoltaic panel according to one preferred embodiment of this invention;

FIG. 2 illustrates a cross-sectional view taken along 2-2′ of the photovoltaic panel as illustrated in FIG. 1; and

FIG. 3 illustrates a flowchart for processing an edge of a photovoltaic panel according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The disclosure herein provides a cost-effective method for processing an edge of a photovoltaic panel, i.e. for establishing an electrical isolation on an edge of a photovoltaic panel. This cost-effective method combines sandblasting and laser scribing to establish an electrical isolation with a width larger than 12 mm. The details of this processing method are further described in the following embodiments.

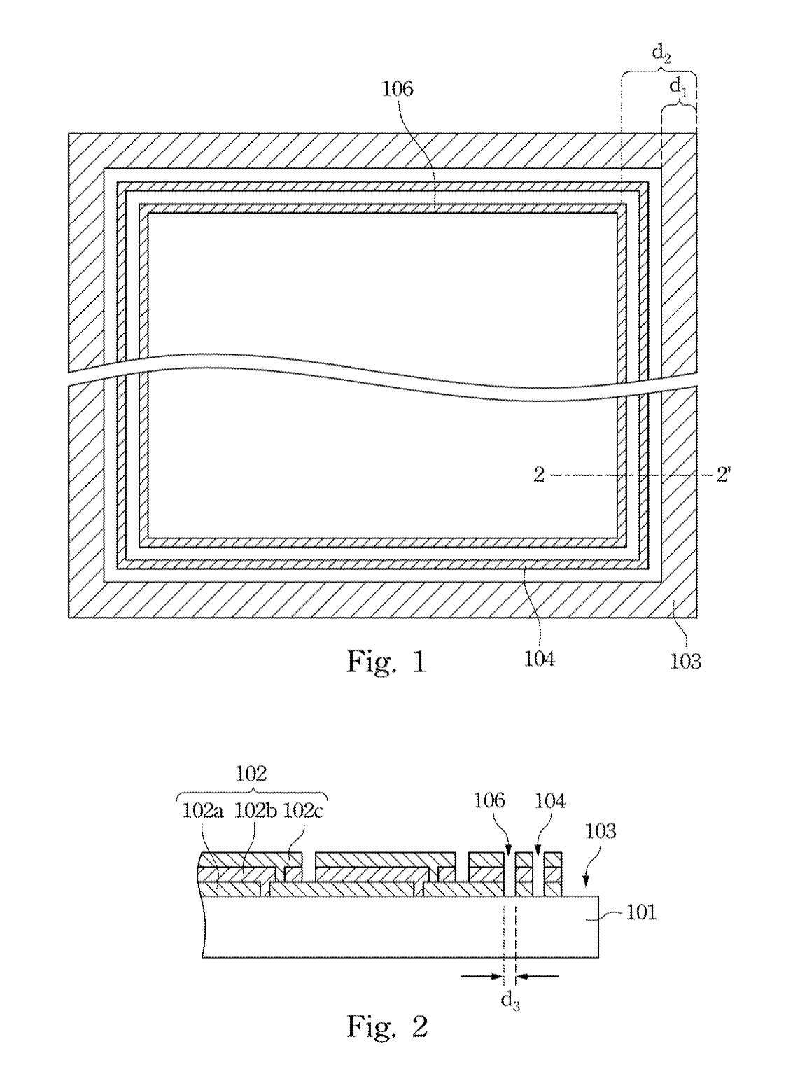

Referring to FIG. 1 and FIG. 2, wherein FIG. 1 illustrates a top view of a photovoltaic panel according to one preferred embodiment of this invention, and FIG. 2 illustrates a cross-sectional view taken along 2-2′ of the photovoltaic panel as illustrated in FIG. 1. An edge of a photovoltaic panel 100 is processed to form a sandblasted edge section 103 and at least two laser scribed grooves (104, 106) as an electrical isolation. The photovoltaic panel 100 basically includes a substrate 101 (e.g. a glass substrate) and at least a stack 102 of three films (102a, 102b, 102c) formed on the substrate 101. The stack 102 of three films includes a plurality of photovoltaic cells, which are electrically connected with each other. Sandblasting and laser scribing are used to remove the edge section of the stack 102 of three films (102a, 102b, 102c) such that the electrical isolation can be established. The films (102a, 102c) are electrically-conductive films and the film 102b is a photovoltaic film.

Because sand-blasting a wide range of electrical isolation (e.g. more than 15 mm in width) is not cost-effective, extra laser scribing is used to widen the width d₂ of electrical isolation. Thus, the wide range of electrical isolation includes a sandblasted edge section 103 (e.g. ranging from about 9 mm to about 12 mm in width d₁) and laser-scribed grooves. Due to the width of laser-scribing groove (e.g. the width d₃ is about 250 μm), at least two laser-scribed grooves are preferred. If a wider range of electrical isolation (e.g. more than 20 mm in width), more laser-scribed grooves may be needed to establish effective electrical isolation. With this regard, a wide range of electrical isolation can be established with a cost-effective way without modifying sandblasting hardware. In this embodiment, the two laser-scribed grooves (104, 106) are arranged in parallel with the sandblasted edge section 103.

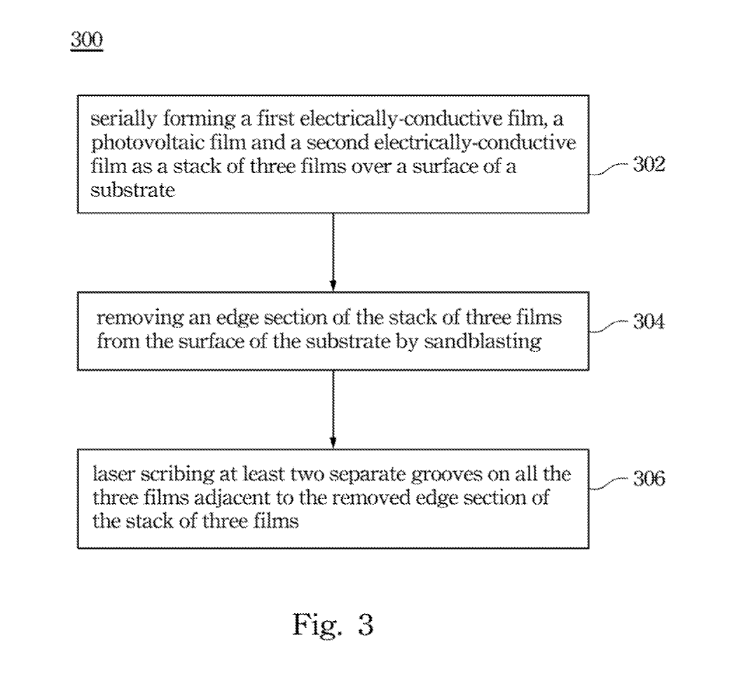

Referring to FIG. 3, which illustrates a flowchart 300 for processing an edge of a photovoltaic panel according to one preferred embodiment of this invention.

In step 302, a first electrically-conductive film (e.g. 102a), a photovoltaic film (e.g. 102b) and a second electrically-conductive film (e.g. 102c) are serially formed as a stack of three films over a surface of a substrate, e.g. an upper surface, by chemical vapor deposition. The first and second electrically-conductive films can be but not limited to transparent conducting oxide films, such as SnO₂, ZnO or ITO, etc. The photovoltaic film basically includes a laminated layer a-Si layer constituting a PN or PIN junction so as to generate power. The first and second electrically-conductive films are used to establish an electrical connection between the photovoltaic film and an output terminal.

In step 304, a sandblasting processing is utilized to remove an edge section of the stack of three films. Due to the sandblasting's hardware limitations, the sandblasted edge section is within a width ranging about 9 mm to about 12 mm. Modifying sandblasting's hardware to widen the sandblasted edge section would result in a big increase in cost for processing the edge of a photovoltaic panel.

In step 306, a laser scribing process is used to form at least two separate grooves on the stack of three films to widen a range of the electrical isolation up to about 15 mm or about 20 mm. That is, the sandblasted edge section and at least two separate grooves are located within an area of about 20 mm or about 15 mm in width. In this embodiment, a 1064 nm plus 532 nm infrared lasers are selectively utilized to scribe the stack of the three films, so as to respectively define the two separate grooves adjacent to the removed edge section of the stack of three films.

Due to the combination of sandblasting and laser scribing for processing an edge of a photovoltaic panel, a wider range of electrical isolation can be established on an edge of a photovoltaic panel with a cost-effective way and without modifying sandblasting's hardware.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for processing an edge of a photovoltaic panel comprising:
serially forming a first electrically-conductive film, a photovoltaic film and a second electrically-conductive film as a stack of three films over a surface of a substrate;
removing an edge section of the stack of three films from the surface of the substrate by sandblasting; and
laser scribing at least two separate grooves on all the three films adjacent to the removed edge section of the stack of three films.

2. The method of claim 1, wherein the removed edge section of the stack of three films ranges from about 9 mm to about 12 mm in width.

3. The method of claim 1, wherein the removed edge section of the stack of three films is less than 12 mm in width.

4. The method of claim 1, wherein the removed edge section of the stack of three films and at least two separate grooves are located within an area of about 20 mm or about 15 mm in width.

5. The method of claim 4, wherein the least two separate grooves are in parallel with the removed edge section of the stack of three films.

6. The method of claim 1, wherein the least two separate grooves are in parallel with the removed edge section of the stack of three films.

7. The method of claim 1, wherein the first electrically-conductive film is a transparent conducting oxide film.

8. The method of claim 1, wherein the second electrically-conductive film is a transparent conducting oxide film.

9. The method of claim 1, wherein each of the at least two separate grooves is about 250 μm width.

10. The method of claim 1, wherein the substrate is a glass substrate.
